(19) United States
(12) Patent Application Publication
(10) Pub. No.: US 2025/0218863 A1
(43) Pub. Date: Jul. 3, 2025

(54) ORTHOGONAL METAL LINES AT THE SAME METAL LEVEL

(71) Applicant: International Business Machines Corporation, Armonk, NY (US)

(72) Inventors: Nicholas Anthony Lanzillo, Wynantskill, NY (US); Ruilong Xie, Niskayuna, NY (US); David Wolpert, POUGHKEEPSIE, NY (US); Albert M. Chu, Nashua, NH (US); Lawrence A. Clevenger, Saratoga Springs, NY (US); Brent A. Anderson, Jericho, VT (US)

(21) Appl. No.: 18/400,791

(22) Filed: Dec. 29, 2023

(51) Int. Cl. H01L 21/768; H01L 23/522; H01L 23/528

(52) U.S. Cl. CPC H01L 21/76816; H01L 21/7684; H01L 21/76843; H01L 21/76877; H01L 23/5226; H01L 23/528

(57) ABSTRACT

A semiconductor interconnect structure and formation thereof. The semiconductor interconnect structure includes a first set of metal lines running along a first orientation, and a second set of metal lines having an insulating liner and running along a second orientation. The second set of metal lines are embedded within the first set of metal lines at respective cross points between the first and second set of metal lines, such that the second set of metal lines are located in a same metal level as the first set of metal lines.

### BACKGROUND

The present disclosure generally relates to fabrication methods and structures for semiconductor devices, and more specifically, to fabricating a semiconductor interconnect structure having orthogonal metal lines at the same metal level.

For an integrated circuit (IC) device to be functional, multi-level or multi-layered interconnection schemes such as, for example, metal wiring formed by additive manufacturing processes (e.g., single damascene processes or dual damascene processes), subtractive manufacturing processes (e.g., subtractive etching processes), and combinations thereof, are fabricated in the back-end-of-the-line (BEOL) of the device to connect the circuit elements distributed in the front-end-of-the-line (FEOL) of the device. Connections between the metal lines of the different interconnect levels, called vias, allow signals and power to be transmitted between one level to the next.

### SUMMARY

According to one embodiment of the present invention, a semiconductor interconnect structure is provided. The semiconductor interconnect structure includes a first set of metal lines running along a first orientation, and a second set of metal lines having an insulating liner and running along a second direction. The second set of metal lines are embedded within the first set of metal lines at respective cross points between the first and second sets of metal lines, such that the second set of metal lines are located in a same metal level as the first set of metal lines.

According to another embodiment of the present invention, a semiconductor interconnect structure is provided. The semiconductor interconnect structure includes a first set of metal lines having an insulating liner and running along a first orientation, and second set of metal lines running along a second orientation. The first set of metal lines are encapsulated by the second set of metal lines at respective cross points between the first and second sets of metal lines, such that the first set of metal lines are located in a same metal level as the second set of metal lines.

According to another embodiment of the present invention, a method of forming a semiconductor interconnect structure is provided. The method includes forming a first set of metal lines running along a first orientation. The method further includes forming a second set of metal lines running along a second orientation, such that the second set of metal lines intersect the first set of metal lines at respective cross points between the first and second sets of metal lines, and the second set of metal lines are located in a same metal level as the first set of metal lines.

### BRIEF DESCRIPTION OF THE SEVERAL VIEWS OF THE DRAWINGS

FIG. 1 illustrates a top view of a semiconductor interconnect structure, generally designated 100, in accordance with at least one embodiment of the present invention.

FIGS. 2A, 2B illustrate cross-sectional views, taken along corresponding lines 10, 20 of FIG. 1, of an initial semiconductor interconnect structure, generally designated as semiconductor interconnect structure 200, in accordance with at least one embodiment of the present invention.

FIGS. 3A, 3B illustrate cross-sectional views, taken along corresponding lines 10, 20 of FIG. 1, of semiconductor interconnect structure 200 depicted in FIGS. 2A, 2B after performing subsequent processing steps, generally designated as semiconductor interconnect structure 300, in accordance with at least one embodiment of the present invention.

FIGS. 4A, 4B illustrate cross-sectional views, taken along corresponding lines 10, 20 of FIG. 1, of semiconductor interconnect structure 300 depicted in FIGS. 3A, 3B after performing subsequent processing steps, generally as designated semiconductor interconnect structure 400, in accordance with at least one embodiment of the present invention.

FIG. 5 illustrates a cross-sectional view of semiconductor interconnect structure 100 of FIG. 1 taken along corresponding line 10, generally designated as semiconductor interconnect structure 500, in accordance with at least one embodiment of the present invention.

FIG. 6 illustrates a cross-sectional view of semiconductor interconnect structure 100 of FIG. 1 taken along corresponding line 30, generally designated as semiconductor interconnect structure 600, in accordance with at least one embodiment of the present invention.

FIG. 7 illustrates a cross-sectional view of semiconductor interconnect structure 100 of FIG. 1 taken along corresponding line 40, generally designated as semiconductor interconnect structure 700, in accordance with at least one embodiment of the present invention.

FIG. 8 illustrates a cross-sectional view of semiconductor interconnect structure 100 of FIG. 1 taken along corresponding line 50, generally designated as semiconductor interconnect structure 800, in accordance with at least one embodiment of the present invention.

FIG. 9 illustrates a top view of a semiconductor interconnect structure, generally designated 900, in accordance with at least one embodiment of the present invention.

FIG. 10 illustrates a cross-sectional view, taken along corresponding line 910 of FIG. 9, of an initial semiconductor interconnect structure, generally designated as 1000, in accordance with at least one embodiment of the present invention.

FIG. 11 illustrates a cross-sectional view, taken along corresponding line 910 of FIG. 9, of semiconductor interconnect structure 1000 depicted in FIG. 10 after performing subsequent processing steps, generally designated as semiconductor interconnect structure 1100, in accordance with at least one embodiment of the present invention.

FIG. 12 illustrates a cross-sectional view, taken along corresponding line 910 of FIG. 1, of semiconductor interconnect structure 1100 depicted in FIG. 11 after performing subsequent processing steps, generally designated as semiconductor interconnect structure 1200, in accordance with at least one embodiment of the present invention.

FIG. 13 illustrates a cross-sectional view of semiconductor interconnect structure 900 of FIG. 9 taken along corresponding line 910, generally designated as semiconductor interconnect structure 1300, in accordance with at least one embodiment of the present invention.

FIG. 14 illustrates a cross-sectional view of semiconductor interconnect structure 900 of FIG. 9 taken along corresponding line 920, generally designated as semiconductor interconnect structure 1400, in accordance with at least one embodiment of the present invention.

FIG. 15 illustrates a cross-sectional view of semiconductor interconnect structure 900 of FIG. 9 taken along corresponding line 930, generally designated as semiconductor interconnect structure 1500, in accordance with at least one embodiment of the present invention.

FIG. 16 illustrates a cross-sectional view of semiconductor interconnect structure 900 of FIG. 9 taken along corresponding line 940, generally designated as semiconductor interconnect structure 1600, in accordance with at least one embodiment of the present invention.

### DETAILED DESCRIPTION

According to one embodiment of the present invention, a first semiconductor interconnect structure is provided. The first semiconductor interconnect structure includes a first set of metal lines running along a first orientation. The first semiconductor interconnect structure further includes a second set of metal lines having an insulating liner and running along a second orientation. The second set of metal lines are embedded within the first set of metal lines at respective cross points between the first and second set of metal lines, such that the second set of metal lines are located in a same metal level as the first set of metal lines.

One technical advantage realized by the first semiconductor interconnect structure of the present invention is a reduction in the height of the interconnect stack. By forming different types of metal lines within the same metal level, fewer metal levels are required, which results in a shorter, and more compact, interconnect stack. This also results in an additional technical advantage of the interconnect stack having reduced thermal resistance since the reduction in the number of metal levels allows for heat to be able to be dissipated more efficiently from the shortened interconnect stack.

Another technical advantage realized by the first semiconductor interconnect structure of the present invention is increased decoupling capacitance. For example, in some embodiments, the first semiconductor interconnect structure may be implemented as part of a backside power delivery network (BSPDN), in which the first set of metal lines are power lines and the second set of metal lines are ground lines. In this case, since the first set of metal lines and the second set of metal lines are extremely close to each other (i.e., only a thin insulating liner separates the first set of metal lines and the second set of metal lines at their respective cross points), a large amount of capacitance is generated between the first and second sets of metal lines, which ultimately reduces power supply noise.

In an embodiment, the first orientation that the first set of metal lines run along is orthogonal to the second orientation that the second set of metal lines run along. This results in a technical effect of the first set of metal lines being perpendicular to the second set of metal lines.

In an embodiment, the first orientation that the first set of metal lines run along is parallel to the second orientation that the second set of metal lines run along. This results in a technical effect of the first set of metal lines being parallel to the second set of metal lines.

In an embodiment, a top surface of the first set of metal lines is substantially coplanar with a top surface of the second set of metal lines, and a bottom surface of the first set of metal lines is located below a bottom surface of the second set of metal lines. This results in a technical effect of the first and second sets of metal lines being formed in a same metal level.

In an embodiment, a first pitch between respective metal lines in the first set of metal lines is greater than a second pitch between respective metal lines in the second set of metal lines. This results in a technical effect of a first spacing between respective metal lines in the first set of metal lines being greater than a second spacing between respective metal lines in the second set of metal lines. This also results in a technical advantage of ease of integration of tight pitch lines with relaxed pitch lines. Forming tight pitch lines above relaxed pitch lines is typically difficult. However, this process is simplified by initially forming the first set of metal lines having a relaxed pitch, and embedding the second set of metal lines having a tight pitch within the first set of metal lines. Additionally, the ease of integration in forming tight pitch metal lines above relaxed pitch metals lines also results in a technical advantage of being able to form semiconductor devices (e.g., transistors, capacitors, resistors) on top of the interconnect stack in addition to below the interconnect stack by embedding tight pitch metal lines (i.e., the second set of metal lines) within relaxed pitch metal lines (i.e., the first set of metal lines) at the topmost metal level of the interconnect stack.

In an embodiment, a first pitch between respective metal lines in the first set of metal lines is equal to or less than a second pitch between respective metal lines in the second set of metal lines. This results in a technical effect of a first spacing between respective metal lines in the first set of metal lines being less than or equal to a second spacing between respective metal lines in the second set of metal lines.

In an embodiment, the first set of metal lines and the second set of metal lines are formed from different conductive metal materials. This results in a technical effect of the first and second sets of metal lines formed in the same metal level having different degrees of electrical conductivity.

In an embodiment, the first set of metal lines and the second set of metal lines are formed from the same conductive metal materials. This results in a technical effect of the first and second sets of metal lines formed in the same metal level having the same degree of electrical conductivity.

In an embodiment, the first and second sets of metal lines are formed from an additive manufacturing process. This results in a technical effect of tight pitch metal lines (i.e., the second set of metal lines) being embedded within relaxed pitch metal lines (i.e., the first set of metal lines) within the same metal level.

According to another embodiment of the present invention, a second semiconductor interconnect structure is provided. The second semiconductor interconnect structure includes a first set of metal lines having an insulating liner and running along a first orientation. The second semiconductor interconnect structure further includes a second set of metal lines running along a second orientation. The first set of metal lines are encapsulated by the second set of metal lines at respective cross points between the first and second sets of metal lines, such that the first set of metal lines are located in a same metal level as the second set of metal lines.

One technical advantage realized by the second semiconductor interconnect structure of the present invention is a reduction in the height of the interconnect stack. By forming different types of metal lines within the same metal level, fewer metal levels are required, which results in a shorter, and more compact, interconnect stack. This also results in an additional technical advantage of an interconnect stack having reduced thermal resistance since the reduction in the number of metal levels allows for heat to be able to be dissipated more efficiently from the shortened interconnect stack.

Another technical advantage realized by the first semiconductor interconnect structure of the present invention is increased decoupling capacitance. For example, in some embodiments, the first semiconductor interconnect structure may be implemented as part of a backside power delivery network (BSPDN), in which the first set of metal lines are power lines and the second set of metal lines are ground lines. In this case, since the first set of metal lines and the second set of metal lines are extremely close to each other (i.e., only a thin insulating liner separates the first set of metal lines and the second set of metal lines at their respective cross points), a large amount of capacitance is generated between the first and second sets of metal lines, which ultimately reduces power supply noise.

In an embodiment, the first orientation that the first set of metal lines run along is orthogonal to the second orientation that the second set of metal lines run along. This results in a technical effect of the first set of metal lines being perpendicular to the second set of metal lines.

In an embodiment, the first orientation that the first set of metal lines run along is parallel to the second orientation that the second set of metal lines run along. This results in a technical effect of the first set of metal lines being parallel to the second set of metal lines.

In an embodiment, a bottom surface of the first set of metal lines is substantially coplanar with a bottom surface of the second set of metal lines, and a top surface of the first set of metal lines is located below a top surface of the second set of metal lines. This results in a technical effect of the first and second sets of metal lines being formed in a same metal level.

In an embodiment, a first pitch between respective metal lines in the first set of metal lines is less than a second pitch between respective metal lines in the second set of metal lines. This results in a technical effect of a first spacing between respective metal lines in the first set of metal lines being less than a second spacing between respective metal lines in the second set of metal lines.

In an embodiment, a first pitch between respective metal lines in the first set of metal lines is greater than or equal to a second pitch between respective metal lines in the second set of metal lines. This results in a technical effect of a first spacing between respective metal lines in the first set of metal lines being greater than or equal to a second spacing between respective metal lines in the second set of metal lines.

In an embodiment, the first set of metal lines and the second set of metal lines are formed from different conductive metal materials. This results in a technical effect of the first and second sets of metal lines formed in the same metal level having different degrees of electrical conductivity.

In an embodiment, the first set of metal lines and the second set of metal lines are formed from the same conductive metal materials. This results in a technical effect of the first and second sets of metal lines formed in the same metal level having the same degree of electrical conductivity.

In an embodiment, the first and second sets of metal lines are formed from a subtractive manufacturing process. This results in a technical effect of tight pitch metal lines (i.e., the first set of metal lines) being encapsulated by relaxed pitch metal lines (i.e., the first set of metal lines) within the same metal level.

According to another embodiment of the present invention, a method of forming a semiconductor interconnect structure is provided. The method includes forming a first set of metal lines running along a first orientation. The method further includes forming a second set of metal lines running along a second orientation, such that the second set of metal lines intersect the first set of metal lines at respective cross-points between the first and second sets of metal lines, and the second set of metal lines are located in a same metal level as the first set of metal lines.

One technical advantage realized by the method of forming the semiconductor interconnect structure of the present invention is a reduction in the height of the interconnect stack. By forming different types of metal lines within the same metal level, fewer metal levels are required, which results in a shorter, and more compact, interconnect stack. This also results in an additional technical advantage of the interconnect stack having reduced thermal resistance since the reduction in the number of metal levels allows for heat to be able to be dissipated more efficiently from the shortened interconnect stack.

Another technical advantage realized by the method of forming the semiconductor interconnect structure of the present invention is increased decoupling capacitance. For example, in some embodiments, the first semiconductor interconnect structure may be implemented as part of a backside power delivery network (BSPDN), in which the first set of metal lines are power lines and the second set of metal lines are ground lines. In this case, since the first set of metal lines and the second set of metal lines are extremely close to each other (i.e., only a thin insulating liner separates the first set of metal lines and the second set of metal lines at their respective cross points), a large amount of capacitance is generated between the first and second sets of metal lines, which ultimately reduces power supply noise.

In an embodiment, forming the first set of metal lines running along the first orientation includes: depositing a first insulating material onto a substrate to form an insulating layer, etching the insulating layer to form a first set of line openings within the insulating layer, depositing a metal liner material to form a metal liner within the first set of line openings, and depositing a first conductive metal material on top of the metal liner to fill the first set of line openings. This results in a technical effect of the first set of metal lines being formed by an additive manufacturing process.

In an embodiment, forming the first second set of metal lines running along the second orientation includes: etching the first conductive metal material of the first set of lines to form a second set of line openings within the first set of metal lines, depositing a second insulating material to form an insulating liner within the second set of line openings, and depositing a second conductive metal material on top of the insulating liner to fill the second set of line openings. This results in a technical effect of the second set of metal lines being formed by an additive manufacturing process. This also results in a technical effect of the second set of metal lines being embedded within the first set of metal lines at the respective cross points between the first and second set of metal lines. Additionally, this results in a technical effect of the second set of metal lines being formed within the same metal level as the first set of metal lines.

In an embodiment, the first orientation that the first set of metal lines run along is orthogonal to the second orientation that the second set of metal lines run along. This results in a technical effect of the first set of metal lines being perpendicular to the second set of metal lines.

In an embodiment, forming the first set of metal lines running along the first orientation includes: depositing a first conductive metal material onto a substrate, and etching the first conductive metal material to form the first set of metal lines. This results in a technical effect of the first set of metal lines being formed by a subtractive manufacturing process.

In an embodiment, forming the second set of metal lines running along the second orientation includes: conformally depositing a first insulating material onto the first set of metal lines to form an insulating liner, depositing a second conductive metal material onto the insulating liner, and etching the second conductive metal material to form the second set of metal lines. This results in a technical effect of the first set of metal lines being formed by a subtractive manufacturing process. This also results in a technical effect of the first set of metal lines being encapsulated by the second set of metal lines at the respective cross points between the first and second set of metal lines. Additionally, this results in a technical effect of the first set of metal lines being formed with the same metal level as the second set of metal lines.

Exemplary embodiments now will be described more fully herein with reference to the accompanying drawings, in which exemplary embodiments are shown. In the following detailed description, numerous specific details are set forth in order to provide a thorough understanding of various embodiments of the invention. However, it is to be understood that embodiments of the invention may be practiced without these specific details. As such, this disclosure may be embodied in many different forms and should not be construed as limited to the exemplary embodiments set forth herein. Rather, these exemplary embodiments are provided so that this disclosure will be thorough and complete and will fully convey the scope of this disclosure to those skilled in the art. In the description, details of well-known features and techniques may be omitted to avoid unnecessarily obscuring the presented embodiments.

For purposes of the description hereinafter, terms such as “upper”, “lower”, “right”, “left”, “vertical”, “horizontal”, “top”, “bottom”, and derivatives thereof shall relate to the disclosed structures and methods, as oriented in the drawing figures. Terms such as “above”, “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is focused on the distinctive features or elements of various embodiments of the present invention.

As used herein, terms such as “depositing,” “forming,” and the like may refer to the disposition of layers, or portions of materials, in accordance with a given embodiment. Such processes may or may not be different than those used in the standard practice of the art of microcooler device fabrication. Such processes include, but are not limited to, atomic layer deposition (ALD), molecular layer deposition (MLD), chemical vapor deposition (CVD), low-pressure chemical vapor deposition (LPCVD), plasma enhanced chemical vapor deposition (PECVD), limited reaction processing CVD (LRPCVD), ultrahigh vacuum chemical vapor deposition (UHVCVD), metalorganic chemical vapor deposition (MOCVD), physical vapor deposition, sputtering, plating, electroplating, evaporation, ion beam deposition, electron beam deposition, laser assisted deposition, chemical solution deposition, or any combination of those methods.

As used herein, terms, such as “forming,” and the like, may refer to processes that alter the structure and/or composition of one or more layers of material or portions of materials in accordance with a given embodiment. For example, such formation processes may include, but are not limited to, micromachining, microetching, wet and/or dry etching processes, plasma etching processes, or any of the known etching processes in which material is removed.

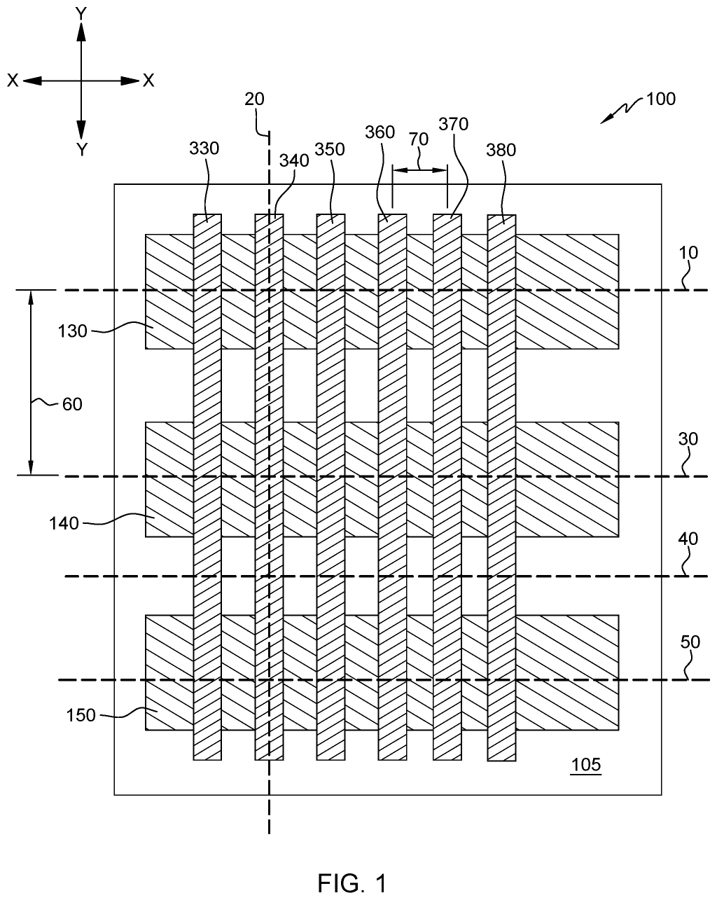

The present invention will now be described in detail with reference to the Figures. FIGS. 1A, 1B-4A, 4B, and 5-16 include various views depicting illustrative steps of methods for manufacturing semiconductor interconnect structures and the resulting semiconductor interconnect structures according to select embodiments of the present invention. One having ordinary skill in the art will appreciate that there are many options available for the formation of the structures described herein and that the following discussion does not limit embodiments to only the techniques described herein.

FIG. 1 depicts a top view of semiconductor interconnect structure 100, in accordance with at least one embodiment of the present invention. For simplicity and ease of understanding, FIG. 1 omits some elements and/or layers so as to not obscure the figure. FIG. 1 illustrates a top-down view of locations and relative orientations of a first set of metal lines (i.e., metal lines 130, 140, 150) running along a first orientation (i.e., along the direction of line X), and a second set of metal lines (i.e., metal lines 330, 340, 350, 360, 370, 380) running along a second orientation (i.e., along the direction of line Y). It should be appreciated that the first set of metal lines and the second set of metal lines may include any number of metal lines, and embodiments of the present invention are not limited to the particular number of metal lines as depicted by FIG. 1.

As further depicted by FIG. 1, the first set of metal lines 130, 140, 150, and the second set of metal lines 330, 340, 350, 360, 370, 380 are formed in the same metal level (e.g., Mx) and are orthogonal to each other. In other words, the first set of metal lines is perpendicular to the second set of metal lines at their respective cross points. In some embodiments, and as depicted by FIG. 1, a first pitch 60 (i.e., the minimum center-to-center distance) between respective metal lines 130, 140, 150 in the first set of metal lines is greater than a second pitch 70 between respective metal lines 330, 340, 350, 360, 370, 380 in the second set of metal lines. However, in other embodiments, the pitch between respective metal lines 130, 140, 150 in the first set of metal lines may be less than, or equal to, the pitch between respective metal lines 330, 340, 350, 360, 370, 380 in the second set of metal lines.

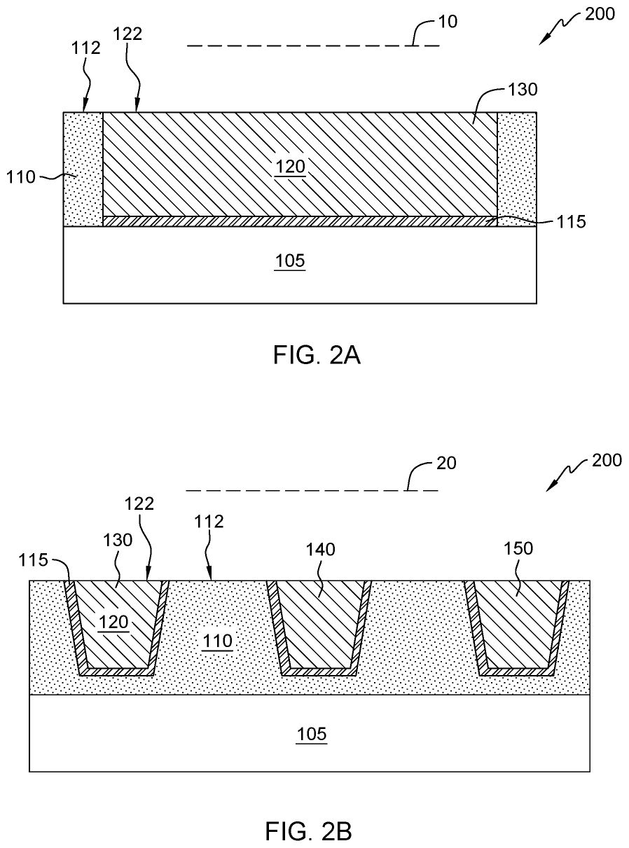

FIGS. 2A, 2B-4A, 4B illustrate a process flow of forming, using an additive manufacturing process, the first set of metal lines 130, 140, 150, and the second set of metal lines 330, 340, 350, 360, 370, 380 as depicted by semiconductor interconnect structure 100 of FIG. 1. FIGS. 2A, 2B illustrate cross-sectional views, taken along corresponding lines 10, 20 of FIG. 1, of an initial semiconductor structure, generally designated 200, in accordance with at least one embodiment of the present invention. In assembly of semiconductor structure 200, and referring to the cross-sectional views of FIGS. 2A, 2B taken along corresponding lines 10, 20 of FIG. 1, an insulating material is initially deposited onto a substrate 105 to form an insulating layer 110, followed by the formation of the first set of metal lines 130, 140, 150 within the insulating layer 110.

In some embodiments, substrate 105 is a bulk semiconductor wafer, such as a bulk silicon (Si), bulk germanium (Ge), bulk silicon germanium (SiGe) and/or bulk III-V semiconductor wafer. Alternatively, in other embodiments, substrate 105 is a semiconductor-on-insulator (SOI) wafer. A SOI wafter includes a SOI layer separated from a substrate by a buried insulator. When the buried insulator is an oxide, it is referred to herein as a buried oxide or BOX. The SOI layer can include any suitable semiconductor, such as Si, Ge, SiGe, and/or a III-V semiconductor.

In some embodiments, substrate 105 may be part of a front-end-of-the-line (FEOL) structure. A FEOL structure is typically present beneath the lowest level of the multilayered interconnect structure and includes a semiconductor substrate having one or more semiconductor devices such as, for example, transistors, capacitors, resistors, and etc. located thereon. In other embodiments, substrate 105 may include one or more interconnect levels of a multilayered interconnect structure, such as a back-end-of-the-line (BEOL) structure. A BEOL structure is typically where the individual semiconductor devices in the FEOL structure are interconnected with one another. In such embodiments, each interconnect level (i.e., metal level) may include one or more electrically conductive structures embedded in an interconnect dielectric material.

Insulating layer 110 may be formed by depositing an insulating material using known techniques including, but not limited to, chemical vapor deposition (CVD), plasma enhanced chemical vapor deposition (PECVD), atomic layer deposition (ALD), physical vapor deposition (PVD), sputtering, chemical solution deposition, or any other suitable deposition techniques. In an embodiment, insulating layer 110 is an interlayer dielectric (ILD). Insulating layer 110 may be composed of an inorganic dielectric material or an organic dielectric material. In some embodiments, insulating layer 110 may be porous. In other embodiments, insulating layer 110 may be non-porous. In some embodiments, insulating layer 110 may have a dielectric constant (all dielectric constants mentioned herein are measured relative to a vacuum, unless otherwise stated) that is about 4.0 or less. In an embodiment, insulating layer 110 may have a dielectric constant of 2.8 or less. These dielectrics having a dielectric constant of 2.8 or less generally have a lower parasitic cross talk as compared to dielectric materials whose dielectric constant is greater than 4.0. Examples of suitable dielectric materials that may be employed as insulating layer 110 include, but are limited to, porous silicates, silicon dioxides, silicon oxynitrides, silicon carbides, silicon nitrides, silicon undoped or doped silicate glass, silsesquioxanes, carbon doped oxides (i.e., organosilicates) that include atoms of Si, C, O and H, and variants thereof, siloxanes, thermosetting polyarylene ethers or any multilayered combination thereof. The term “polyarylene” is used in this present application to denote aryl moieties or inertly substituted aryl moieties which are linked together by bonds, fused rings, or inert linking groups such as, for example, oxygen, sulfur, sulfone, sulfoxide, or carbonyl.

After forming the insulating layer 110 on top of the substrate 105, the first set of metal lines 130, 140, 150 may be formed within the insulating layer 110 using a damascene process. For example, a hard mask material (e.g., silicon nitride, titanium nitride, tantalum nitride, or any suitable inorganic metal-containing material) is deposited (e.g., utilizing known techniques including, but not limited to, chemical vapor deposition (CVD), plasma enhanced chemical vapor deposition (PECVD), atomic layer deposition (ALD), physical vapor deposition (PVD), or sputtering) onto the top surface of the insulating layer 110, and the hard mask material is patterned to form a patterned hard mask (not depicted). Then, using the patterned hard mask, the insulating layer 110 is etched using, for example, reactive ion etching (RIE), ion beam etching (IBE), chemical wet etching, or a combination of IBE and chemical wet etching to form a first set of line openings (not depicted) within the insulating layer.

A metal liner material is then conformally deposited within the first set of line openings to form a metal liner 115, followed by the deposition of a first conductive metal material 120 to fill the first set of line openings. The filling of the first set of line openings with the first conductive metal material 120 results in the formation of the first set of metal lines 130, 140, 150 running along a first orientation (i.e., along the direction of line X as depicted in FIG. 1).

The metal liner material used to form the metal liner 115 and the conductive metal material 120 may be deposited using known techniques including, but not limited to, chemical vapor deposition (CVD), plasma enhanced chemical vapor deposition (PECVD), atomic layer deposition (ALD), physical vapor deposition (PVD), sputtering, chemical solution deposition plating.

The metal liner 115 may include one or more thin layers of material such as, for example, tantalum (Ta), tantalum nitride (TaN), titanium nitride (TiN), hafnium nitride (HfN), cobalt (Co), ruthenium (Ru), tungsten (W), tungsten nitride (WN), titanium-tungsten (TiW), tungsten nitride (WN) manganese (Mn), manganese nitride (MnN) or other barrier materials (or combinations of barrier materials) such as RuTaN, Ta/TaN, CoWP, NiMoP, or NiMoB which are suitable for the given application. The thin metal liner serves as a barrier diffusion layer and adhesion layer. The thickness of the metal liner 115 may vary depending on the deposition process used, as well as the material employed. In some embodiments, the metal liner 115 may have a thickness from 2 nm to 50 nm. However, other thicknesses that are less than 2 nm, or greater than 50 nm can also be employed in embodiments of the present invention.

In some embodiments, an optional plating seed layer (not depicted) can be formed onto the metal liner 115 as well. The optional plating seed layer is employed to selectively promote subsequent electroplating of a pre-selected conductive metal or metal alloy. The optional plating seed layer may be composed of Cu, a Cu alloy, Ir, an Ir alloy, Ru, a Ru alloy (e.g., TaRu alloy) or any other suitable noble metal or noble metal alloy having a low metal-plating overpotential. The optional plating seed layer can be formed by a conventional deposition process including, for example, chemical vapor deposition (CVD), plasma enhanced chemical vapor deposition (PECVD), atomic layer deposition (ALD), or physical vapor deposition (PVD). The thickness of the optional plating seed layer may vary depending on the material of the optional plating seed layer, as well as the technique used in forming the same. Typically, the optional plating seed layer may have a thickness from 2 nm to 80 nm. However, other thicknesses that are less than 2 nm, and greater than 80 nm can also be employed in embodiments of the present invention.

The first conductive metal material 120 may be a metal or metal alloy including, but not limited to, copper (Cu), aluminum (Al), ruthenium (Ru), rhodium (Rh), iridium (Ir), tungsten (W), molybdenum (Mo), nickel (Ni), or an alloy thereof, such as, for example, a Cu—Al alloy. In those embodiments in which a thin conformal copper (Cu) seed layer (not depicted) is deposited over the surface of the metal liner 115, the first set of line openings may be filled by electroplating of Cu. In some embodiments, the metal liner 115 may not be used, in which the first conductive metal material 120 is formed directly onto the exposed surfaces of the patterned insulating layer 110.

Lastly, a planarization process such as, for example, chemical mechanical planarization or polishing (CMP), and/or grinding, may subsequently be performed to remove portions of the metal liner 115 and first conductive metal material 120 located above a top surface 112 of the insulating layer 110. The planarization stops at the top surface 112 of the insulating layer 110, such that a top surface 122 of the first set of metal lines 130, 140, 150 is substantially coplanar with the top surface 112 of the insulating layer 110.

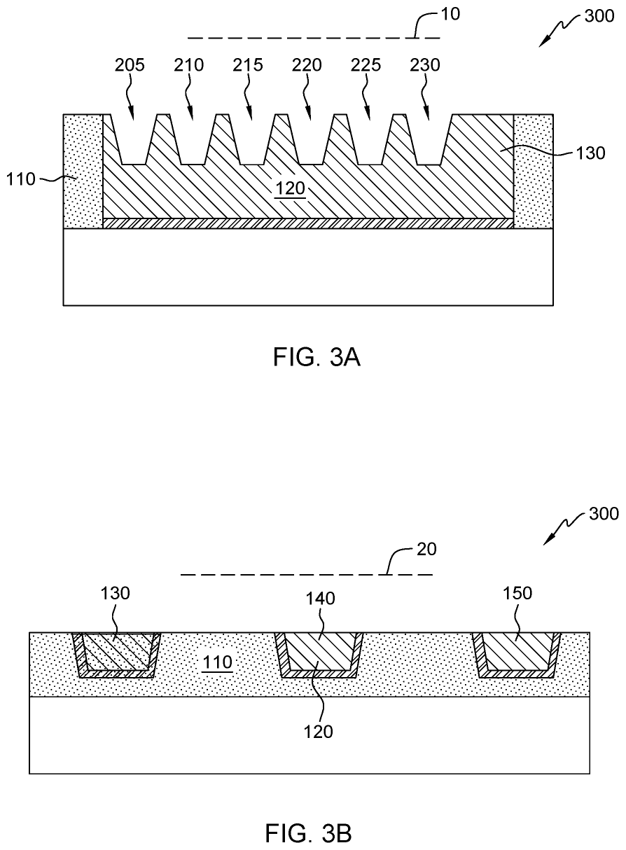

FIGS. 3A, 3B illustrate cross-sectional views of semiconductor interconnect structure 200 depicted in FIGS. 2A, 2B after performing subsequent processing steps, generally designated as semiconductor interconnect structure 300, in accordance with at least one embodiment of the present invention. In assembly of semiconductor interconnect structure 300, and referring to the cross-sectional views of FIGS. 3A, 3B taken along corresponding lines 10, 20 of FIG. 1, a second set of line openings 205, 210, 215, 220, 225, 230 are formed within, and orthogonally to, metal lines 130, 140, 150 of the first set of metal lines.

The second set of line openings 205, 210, 215, 220, 225, 230 may be formed as follows. A hard mask material (e.g., silicon nitride, titanium nitride, tantalum nitride, or any suitable inorganic metal-containing material) is deposited (e.g., utilizing known techniques including, but not limited to, chemical vapor deposition (CVD), plasma enhanced chemical vapor deposition (PECVD), atomic layer deposition (ALD), physical vapor deposition (PVD), or sputtering) onto the insulating layer 110 and the first set of metal lines 130, 140, 150, and patterned to form a patterned hard mask (not depicted). Then, using the patterned hard mask, the insulating layer 110 and the first conductive metal material 120 of the first set of metal lines 130, 140, 150 are etched (using, for example, reactive ion etching (RIE), ion beam etching (IBE), chemical wet etching, or a combination of IBE and chemical wet etching) to form the second set of line openings 205, 210, 215, 220, 225, 230.

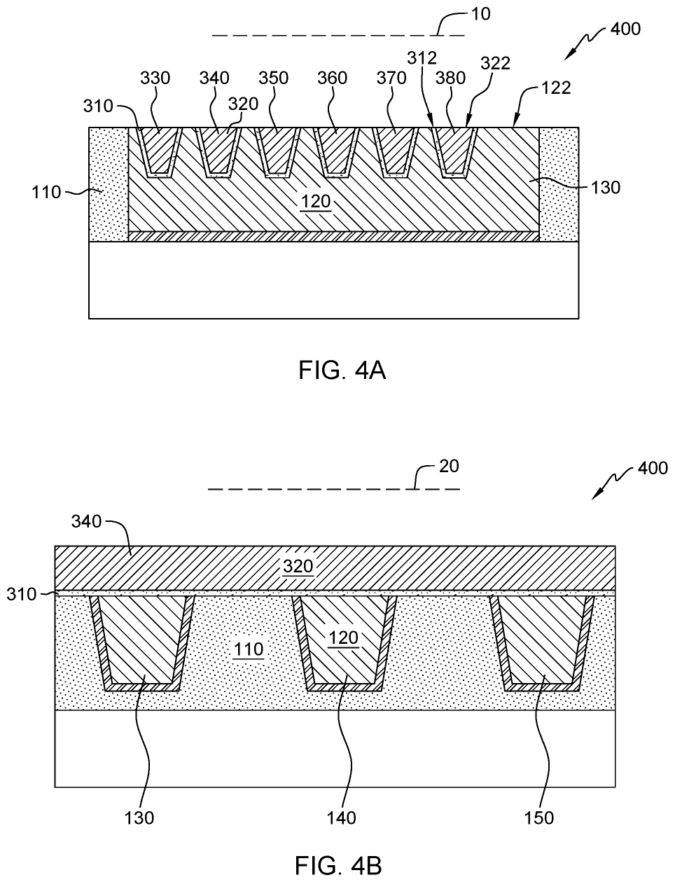

FIGS. 4A, 4B illustrate cross-sectional views of semiconductor structure 300 depicted in FIGS. 3A, 3B after performing subsequent processing steps, generally designated as semiconductor interconnect structure 400, in accordance with at least one embodiment of the present invention. In assembly of semiconductor structure 400, and referring to the cross-sectional views of FIGS. 4A, 4B taken along corresponding lines 10, 20 of FIG. 1, an insulating material is conformally deposited within the second set of line openings 205, 210, 215, 220, 225, 230 (depicted in FIGS. 3A, 3B) to form an insulating liner 310, followed by the deposition of a second conductive metal material 320 to fill the second set of line openings 205, 210, 215, 220, 225, 230. The filling of the second set of line openings 205, 210, 215, 220, 225, 230 with the second conductive metal material 320 results in the formation of the second set of metal lines 330, 340, 350, 360, 370, 380 embedded within, and orthogonal to, the first set of metal lines 130, 140, 150.

The second set of metal lines 330, 340, 350, 360, 370, 380 run along a second orientation (i.e., along the direction of line Y as depicted in FIG. 1) that is orthogonal to the first orientation from which the first set of metal lines 130, 140, 150 run along (i.e., along the direction of line X as depicted in FIG. 1). As depicted by FIGS. 4A, 4B, the second set of metal lines 330, 340, 350, 360, 370, 380 are embedded within the first set of metal lines 130, 140, 150 at respective cross points between the first and second sets of metal lines, such that the second set of metal lines 330, 340, 350, 360, 370, 380 are located within the same metal level (e.g., Mx) as the first set of metal lines 130, 140, 150. As further depicted by FIGS. 4A, 4B, the top surface 122 of the first set of metal lines 130, 140, 150 is substantially coplanar with the top surface 322 of the second set of metal lines, and a bottom surface of the first set of metal lines is located below a bottom surface of the second set of metal lines.

In assembly of semiconductor interconnect structure 400, the insulating material of the insulating liner 310 and the second conductive metal material 320 may be deposited using any of the processes and materials as previously described above with respect to forming the insulating layer 110 and the first conductive metal material 120 of FIGS. 2A, 2B. In some embodiments, and as depicted in FIGS. 4A, 4B, the first conductive metal material 120 used to form the first set of metal lines 130, 140, 150 is a different conductive metal material than the second conductive metal material 320 used to form the second set of metal lines 330, 340, 350, 360, 370, 380. However, in other embodiments, the first conductive metal material 120 used to form the first set of metal lines 130, 140, 150 may be the same conductive metal material as the second conductive metal material 320 used to form the second set of metal lines 330, 340, 350, 360, 370, 380.

Following the deposition of the insulating material of the insulating liner 310 and the second conductive metal material 320, a planarization process such as, for example, chemical mechanical planarization or polishing (CMP), and/or grinding, may be performed to remove portions of the insulating liner 310 and the second conductive metal material 320 located above the top 122 surface of the first set of metal lines 130, 140, 150. The planarization stops at the top surface 122 of the first set of metal lines 130, 140, 150, such that a top surface 312 of the insulating liner and the top surface 322 of the second set of metal lines 330, 340, 350, 360, 370, 380 are substantially coplanar with the top surface 122 of metal line 130.

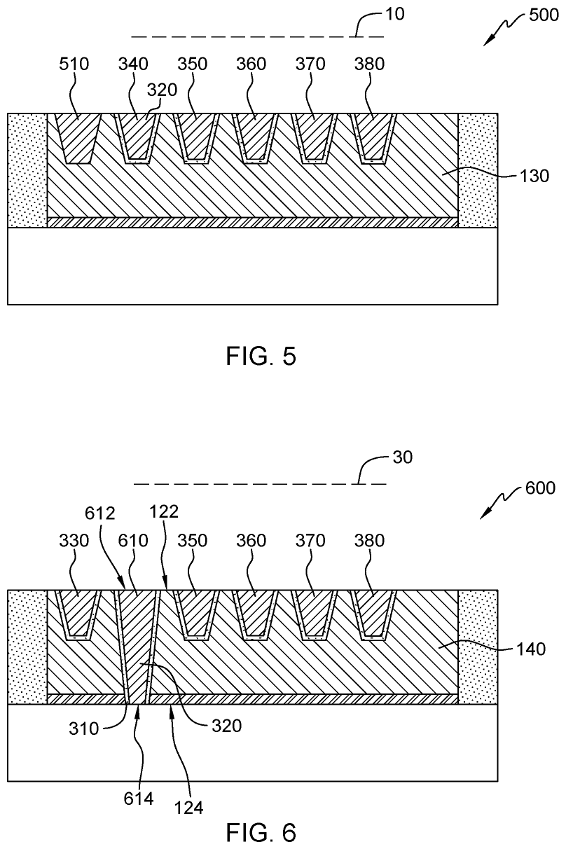

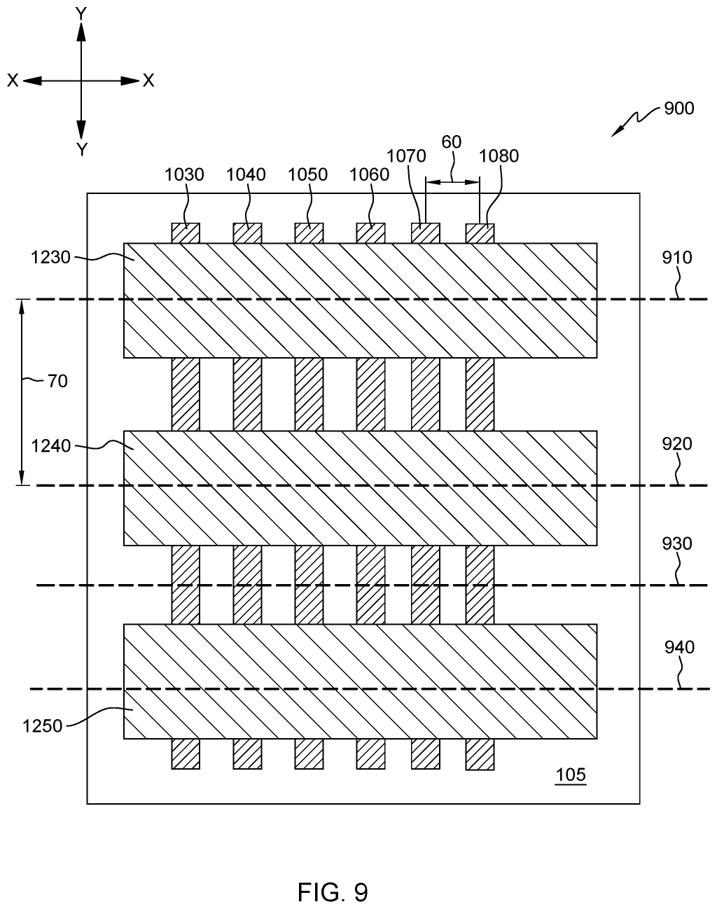

In some embodiments, one or more vias may additionally be formed to connect respective metal lines of the first set of metal lines to respective metal lines of the second set of metal lines formed in the same metal level. For example, and as depicted by the cross-sectional view of semiconductor structure 500 of FIG. 5 taken along corresponding line 10 of FIG. 1, via 510 connects metal line 130 from the first set of metal lines to metal line 330 of the second set of metal lines. Via 510 may be formed through additional masking and etching steps to remove a portion of the insulating liner 310 formed at a cross-point between metal line 330 of the second set of metal lines and metal line 130 of the first set of metal lines prior to depositing the second conductive metal material 320 to form the second set of metal lines 330, 340, 350, 360, 370, 380. This is particularly advantageous in that signals and power can be routed in multiple directions (i.e., along the direction of line X, and along the direction of line Y as depicted in FIG. 9) between metal lines formed in the same metal level (e.g., Mx). This is also particularly advantageous in that the removal of the insulating liner 310 formed at a cross-point between metal line 330 of the second set of metal lines and metal line 130 of the first set of metal lines results in the formation of an ultra-low resistance via connection due to the increased via contact area between the via 510 and the metal line 130.

In some embodiments, one or more vias may additionally be formed through one or more metal lines of the first set of metal lines. For example, and as depicted by the cross-sectional view of semiconductor structure 600 of FIG. 6 taken along corresponding line 30 of FIG. 1, the via 610 extends completely through metal line 140 of the first set of metal lines, such that a top surface 612 of the via 610 is substantially coplanar with a top surface 122 of metal line 140, and a bottom surface 614 of the via 610 is substantially coplanar with a bottom surface 124 of metal line 140. The via 610 may be formed by additional masking and etching steps to extend a portion of the line opening 210 (depicted in FIG. 3A) formed at a cross point with metal line 140 completely through the metal line 140, followed by an etch back of the insulating liner 310 prior to the deposition of the second conductive metal material 320 to form the second set of metal lines 330, 340, 350, 360, 370, 380.

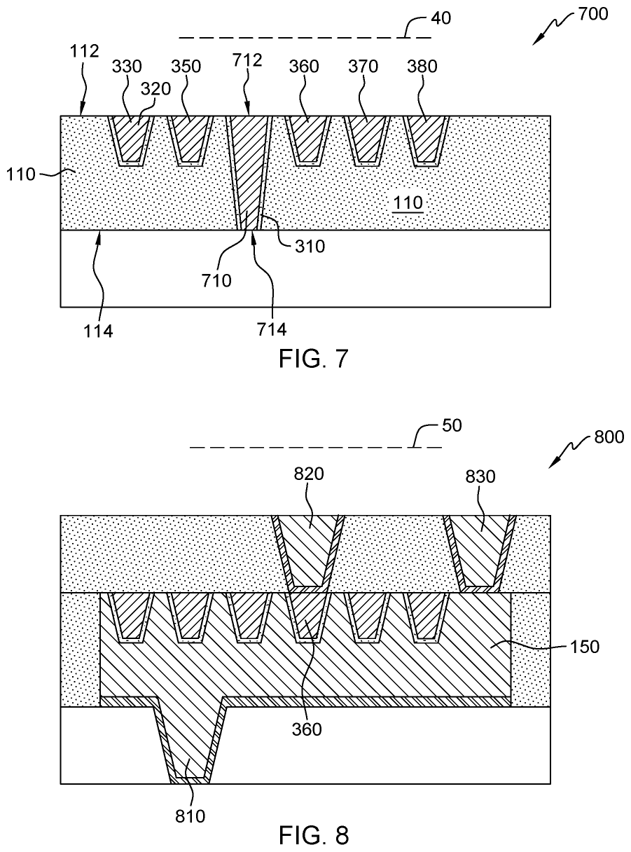

In some embodiments, one or more vias may additionally be formed within the regions of the insulating layer 110 located between the first set of metal lines 130, 140, 150. For example, and as depicted by the cross-sectional view of semiconductor structure 700 of FIG. 7 taken along corresponding line 40 of FIG. 1, the via 710 extends completely through a portion of the insulating layer 110 located between metal line 140 (depicted in FIG. 1) and metal line 150 (depicted in FIG. 1) of the first set of metal lines, such that a top surface 712 of the via 700 is substantially coplanar with the top surface 112 of the insulating layer 110 and a bottom surface 714 of the via is substantially coplanar with a bottom surface 114 of the insulating layer 110. The via 710 may be formed by additional masking and etching steps to extend a portion of the line opening 215 (depicted in FIG. 3A) formed at a cross point with a region of the insulating layer 110 located between metal line 140 and metal line 150 of the first set of metal lines completely through the insulating layer 110, followed by an etch back of insulating liner 310 prior to the deposition of the second conductive metal material 320 to form the second set of metal lines 330, 340, 350, 360, 370, 380.

In some embodiments, one or more vias may additionally be formed on top of or below respective metal lines of the first or second sets of metal lines. For example, and as depicted by the cross-sectional view of semiconductor structure 800 of FIG. 8 taken along corresponding line 50 of FIG. 1, the via 810 is formed below the metal line 150 of the first set of metal lines. Similarly, the via 820 is formed on top of metal line 360 of the second set of metal lines and the via 830 is formed on top of metal line 150 of the first set of metal lines. The vias 810, 820, 830 may be formed using one or more conventional semiconductor manufacturing processes (e.g., a damascene process or a subtractive etch process) for forming a via below or on top of a metal line as known by one of ordinary skill in the art, and as such, a more detailed description of such processes is not presented herein.

FIG. 9 depicts a top view of semiconductor structure 900, in accordance with at least one embodiment of the present invention. For simplicity and ease of understanding, FIG. 9 omits some elements and/or layers so as to not obscure the figure. FIG. 9 illustrates a top-down view of locations and relative orientations of a first set of metal lines (i.e., metal lines 1030, 1040, 1050, 1060, 1070, 1080) running along a first orientation (i.e., along the direction of line Y) and a second set of metal lines (i.e., metal lines 1230, 1240, 1250) running along a second orientation (i.e., along the direction of line X). It should be appreciated that the first set of metal lines and the second set of metal lines may include any number of metal lines, and embodiments of the present invention are not limited to the particular number of metal lines as depicted by FIG. 9.

As further depicted by FIG. 9, the first set of metal lines 1030, 1040, 1050, 1060, 1070, 1080 and the second set of metal lines 1230, 1240, 1250 are formed in the same metal level (e.g., Mx) and are orthogonal to each other. In other words, the first set of metal lines is perpendicular to the second set of metal lines at their respective points of intersection. In some embodiments, and as depicted by FIG. 9, a first pitch 60 (i.e., the minimum center-to-center distance) between the respective metal lines 1030, 1040, 1050, 1060, 1070, 1080 in the first set of metal lines is less than a second pitch 70 between the respective metal lines 1230, 1240, 1250 in the second set of metal lines. However, in other embodiments, the pitch between the respective metal lines 1030, 1040, 1050, 1060, 1070, 1080 in the first set of metal lines may be less than or equal to the pitch between the respective metal lines 1230, 1240, 1250 in the second set of metal lines.

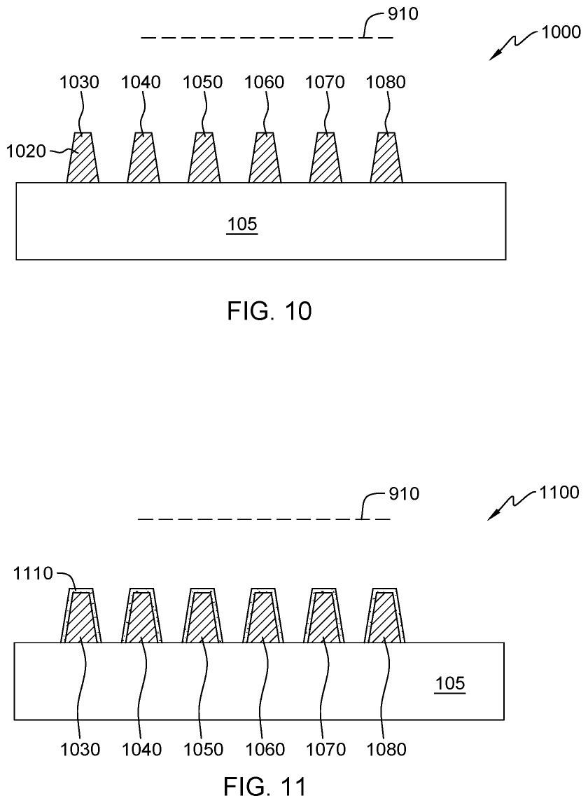

FIGS. 10-12 illustrate a process flow for forming, using a subtractive manufacturing process, the first set of metal lines 1030, 1040, 1050, 1060, 1070, 1080, and the second set of metal lines 1230, 1240, 1250 as depicted by semiconductor interconnect structure 900 of FIG. 9. FIG. 10 illustrates a cross-sectional view, taken along corresponding line 910 of FIG. 9, of an initial semiconductor structure 1000, in accordance with at least one embodiment of the present invention. In assembly of semiconductor structure 1000, and referring to the cross-sectional view of FIG. 10 taken along corresponding line 910 FIG. 10, a first conductive metal material 1020 is initially deposited onto substrate 105, followed by the etching of the first conductive metal material 1020 to form the first set of metal lines 1030, 1040, 1050, 1060, 1070, 1080. The etching of the first conductive metal material 1020 to form the first set of metal lines 1030, 1040, 1050, 1060, 1070, 1080 may generally be referred to herein as a subtractive manufacturing process and the first set of metal lines 1030, 1040, 1050, 1060, 1070, 1080 formed as a result thereof may generally be referred to herein as subtractive metal lines.

The first conductive metal material 1020 may be deposited using known techniques including, but not limited to, chemical vapor deposition (CVD), plasma enhanced chemical vapor deposition (PECVD), atomic layer deposition (ALD), physical vapor deposition (PVD), sputtering, chemical solution deposition plating. The first conductive metal material 1020 may be a metal or metal alloy including, but not limited to, aluminum (Al), ruthenium (Ru), rhodium (Rh), iridium (Ir), tungsten (W), molybdenum (Mo), nickel (Ni), or an alloy thereof, such as, for example, a Cu—Al alloy.

Following the deposition of the first conductive metal material 1020, the first set of metal lines 1030, 1040, 1050, 1060, 1070, 1080 may be formed using subtractive etching. For example, a hard mask material (e.g., silicon nitride, titanium nitride, tantalum nitride, or any suitable inorganic metal-containing material) is deposited (e.g., utilizing known techniques including, but not limited to, chemical vapor deposition (CVD), plasma enhanced chemical vapor deposition (PECVD), atomic layer deposition (ALD), physical vapor deposition (PVD), or sputtering) onto the first conductive metal material 1020, and the hard mask material is patterned to form a patterned hard mask (not depicted). Then, using the patterned hard mask, the first conductive metal material 1020 is etched (using, for example, reactive ion etching (RIE), ion beam etching (IBE), chemical wet etching, or a combination of IBE and chemical wet etching) to form the first set of metal lines 1030, 1040, 1050, 1060, 1070, 1080.

FIG. 11 illustrates a cross-sectional view of semiconductor structure 1000 depicted in FIG. 10 after performing subsequent processing steps, generally designated as semiconductor interconnect structure 1100, in accordance with at least one embodiment of the present invention. In assembly of semiconductor interconnect structure 1100, and referring to the cross-sectional view of FIG. 11 taken along corresponding line 910 of FIG. 9, an insulating material is conformally deposited onto the first set of metal lines 1030, 1040, 1050, 1060, 1070, 1080 to form an insulating liner 1110.

The insulating liner 1110 may be formed by depositing an insulating material using known techniques including, but not limited to, chemical vapor deposition (CVD), plasma enhanced chemical vapor deposition (PECVD), atomic layer deposition (ALD), physical vapor deposition (PVD), sputtering, chemical solution deposition, or any other suitable deposition techniques. The insulating liner 1110 may be formed from any of the materials as previously described above with respect to the insulating materials used to form the insulating layer 110 of FIGS. 2A, 2B. In some embodiments, and as depicted by FIG. 11, an etch back of the insulating liner 1110 is performed to expose the substrate 105 in between the respective metal lines 1030, 1040, 1050, 1060, 1070, 1080 of the first set of metal lines.

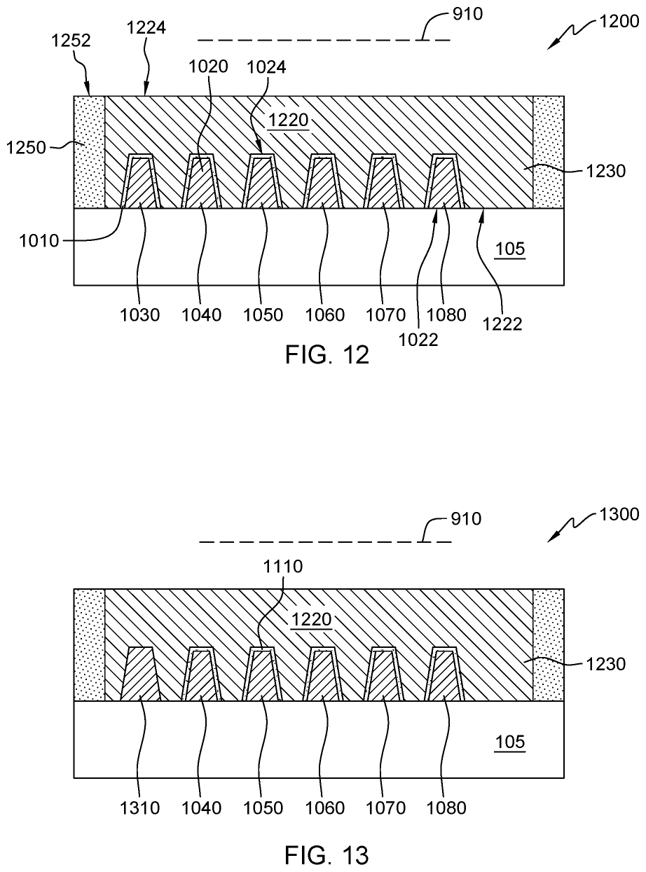

FIG. 12 illustrates a cross-sectional view of semiconductor structure 1100 depicted in FIG. 11 after performing subsequent processing steps, generally designated as semiconductor interconnect structure 1200, in accordance with at least one embodiment of the present invention. In assembly of semiconductor interconnect structure 1200, and referring to the cross-sectional view of FIG. 12 taken along corresponding line 910 of FIG. 9, a second conductive metal material 1220 is deposited onto the insulating liner 1110 formed on top of the first set of metal lines 1030, 1040, 1050, 1060, 1070, 1080, the second conductive metal material 1220 is etched to form a second set of metal lines 1230, 1240, 1250 (metal lines 1240, 150 depicted in FIG. 9) followed by the deposition of an insulating material to form an insulating layer 1250. The etching of the second conductive metal material 1220 to form the second set of metal lines 1230, 1240, 1250 may generally be referred to herein as a subtractive manufacturing process and the second set of metal lines 1230, 1240, 1250 formed as a result thereof may generally be referred to herein as subtractive metal lines.

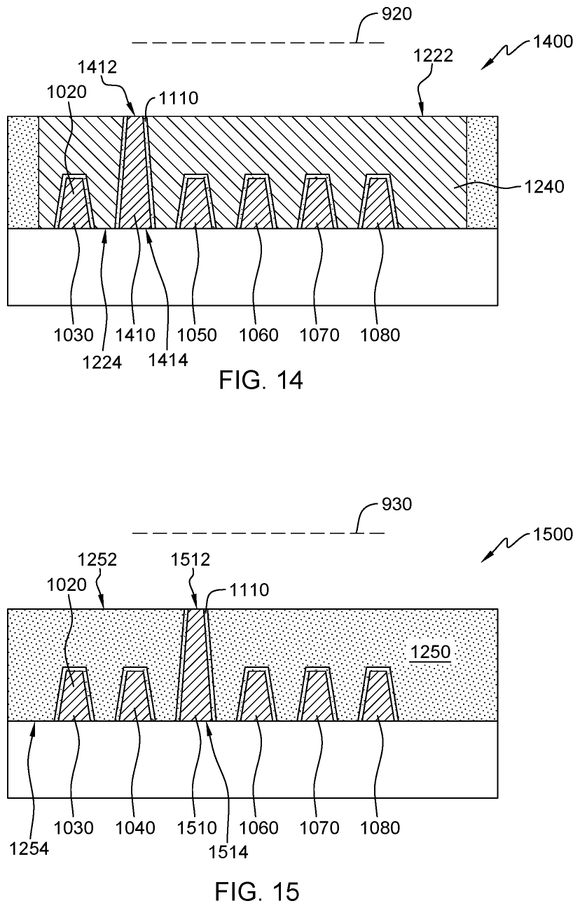

As depicted by FIGS. 9 and 12, the second set of metal lines 1230, 1240, 1250 run along a second orientation (i.e., along the direction of line X) that is orthogonal to the first orientation from which the first set of metal lines 1030, 1040, 1050, 1060, 1070, 1080 run along (i.e., along the direction of line Y). The first set of metal lines are 1030, 1040, 1050, 1060, 1070, 1080 are encapsulated by the second set of metal lines 1230, 1240, 1250 at the respective cross points between the first and second sets of metal lines such that the first set of metal lines 1030, 1040, 1050, 1060, 1070, 1080 are located within the same metal level as the second set of metal lines 1230, 1240, 1250. As further depicted by FIGS. 9 and 12, a bottom surface 1022 of the first set of metal lines 1030, 1040, 1050, 1060, 1070, 1080 is substantially coplanar with a bottom surface 1222 of the second set of metal lines 1230, 1240, 1250 (metal lines 1240, 1250 depicted in FIGS. 14 and 15), and a top surface 1024 of the first set of metal lines 1030, 1040, 1050, 1060, 1070, 1080 is located below a top surface 1224 of the second set of metal lines 1230, 1240, 1250.

In assembly of the semiconductor interconnect structure 1200, the second conductive metal material 1220 may be deposited onto the insulating liner 1110 using known techniques including, but not limited to, chemical vapor deposition (CVD), plasma enhanced chemical vapor deposition (PECVD), atomic layer deposition (ALD), physical vapor deposition (PVD), sputtering, chemical solution deposition plating. The second conductive metal material 1220 may be a metal or metal alloy including, but not limited to, aluminum (Al), ruthenium (Ru), rhodium (Rh), iridium (Ir), tungsten (W), molybdenum (Mo), nickel (Ni), or an alloy thereof, such as, for example, a Cu—Al alloy. In some embodiments, and as depicted in FIGS. 9 and 12, the first conductive metal material 1020 used to form the first set of metal lines 1030, 1040, 1050, 1060, 1070, 1080 is a different conductive metal material than the second conductive metal material 1220 used to form the second set of metal lines 1230, 1240, 1250. However, in other embodiments, the first conductive metal material 1020 used to form the first set of metal lines 1030, 1040, 1050, 1060, 1070, 1080 may be the same conductive metal material as the second conductive metal material 1220 used to form the second set of metal lines 1230, 1240, 1250.

Following the deposition of the second conductive metal material 1220, the second set of metal lines 1230, 1240, 1250 may be formed using subtractive etching. For example, a hard mask material (e.g., silicon nitride, titanium nitride, tantalum nitride, or any suitable inorganic metal-containing material) is deposited (e.g., utilizing known techniques including, but not limited to, chemical vapor deposition (CVD), plasma enhanced chemical vapor deposition (PECVD), atomic layer deposition (ALD), physical vapor deposition (PVD), or sputtering) onto the second conductive metal material 1220, and the hard mask material is patterned to form a patterned hard mask (not depicted). Then, using the patterned hard mask, the second conductive metal material 1220 is etched (using, for example, reactive ion etching (RIE), ion beam etching (IBE), chemical wet etching, or a combination of IBE and chemical wet etching) to form the second set of metal lines 1230, 1240, 1250.

After forming the second set of metal lines 1230, 1240, 1250, an insulating material may be deposited (e.g., using known techniques including, but not limited to, chemical vapor deposition (CVD), plasma enhanced chemical vapor deposition (PECVD), atomic layer deposition (ALD), physical vapor deposition (PVD), sputtering, chemical solution deposition, or any other suitable deposition techniques) to form an insulating layer 1250. The insulating layer 1250 may be formed from any of the insulating materials as previously described above with respect to the insulating materials used to form the insulating layer 110 of FIGS. 2A, 2B.

Lastly, a planarization process such as, for example, chemical mechanical planarization or polishing (CMP), and/or grinding, may subsequently be performed to remove portions of the insulating layer 1250 located above a top surface 1222 of the second set of metal lines 1230, 1240, 1250. The planarization stops at the top surface 1222 of the second set of metal lines 1230, 1240, 1250 (metal lines 1240, 1250 depicted in FIG. 9), such that a top surface 1252 of the insulating layer 1250 is substantially coplanar with the top surface 1222 of the second set of metal lines 1230, 1240, 1250.

In some embodiments, one or more vias may additionally be formed to connect respective metal lines of the first set of metal lines to respective metal lines of the second set of metal lines formed in the same metal level. For example, and as depicted by the cross-sectional view of semiconductor structure 1300 of FIG. 13 taken along corresponding line 910 of FIG. 9, the via 1310 connects metal line 1030 from the first set of metal lines to metal line 1230 (depicted in FIG. 9) of the second set of metal lines. Via 1310 may be formed through additional masking and etching steps to remove a portion of the insulating liner 1110 formed at a cross point between metal line 1030 of the first set of metal lines and metal line 1230 of the second set of metal lines prior to depositing the second conductive metal material 1220 to form the second set of metal lines 1230, 1240, 1250 (metal lines 1240, 1250 depicted in FIG. 9). This is particularly advantageous in that signals and power can be routed in multiple directions (i.e., along the direction of line X, and along the direction of line Y as depicted in FIG. 9) between metal lines formed in the same metal level (e.g., Mx). This is also particularly advantageous in that the removal of the insulating liner 1110 formed at a cross-point between metal line 1030 of the first set of metal lines and metal line 1230 of the second set of metal lines results in the formation of an ultra-low resistance via connection due to the increased via contact area between the via 1310 and the metal line 1230.

In some embodiments, one or more vias may additionally be formed through one or more metal lines of the first set of metal lines. For example, and as depicted by the cross-sectional view of semiconductor structure 1400 of FIG. 14 taken along corresponding line 920 of FIG. 9, the via 1410 extends completely through metal line 1240 of the second set of metal lines, such that a top surface 1412 of the via 1410 is substantially coplanar with a top surface 1222 of metal line 1240, and a bottom surface 1414 of the via 1410 is substantially coplanar with a bottom surface 1224 of metal line 1240. In an embodiment, the via 1410 may be formed by depositing a thicker layer of the first conductive metal material 1020 to allow for the formation of a via having the same height as the metal line 1240. After etching the thicker layer of the first conductive metal material 1020 using one or more etching processes, and the subsequent formation of the insulating liner 1110, an etch back of the insulating liner 1110 formed on top of the via 1410 is performed prior to depositing the second conductive metal material 1220 to form the second set of metal lines 1230, 1240 1250.

In some embodiments, one or more vias may additionally be formed within the regions of the insulating layer 1250 located between the first set of metal lines 1030, 1040, 1050, 1060, 1070, 1080. For example, and as depicted by the cross-sectional view of semiconductor structure 1500 of FIG. 15 taken along corresponding line 930 of FIG. 9, the via 1510 extends completely through a portion of the insulating layer 1250 located between metal line 1240 (depicted in FIG. 9) and metal line 1250 (depicted in FIG. 9) of the second set of metal lines, such that a top surface 1512 of the via 1510 is substantially coplanar with a top surface 1252 of the insulating layer 1250 and a bottom surface 1514 of the via 1510 is substantially coplanar with the bottom surface 1254 of the insulating layer 1250. In an embodiment, the via 1510 may be formed by depositing a thicker layer of the first conductive metal material 1020 to allow for the formation of a via having the same height as the insulating layer 1250. After etching the thicker layer of the first conductive metal material 1020 using one or more etching processes, and the subsequent formation of the insulating liner 1110, an etch back of the insulating liner 1110 formed on top of the via 1510 is performed prior to depositing the insulating layer 1250.

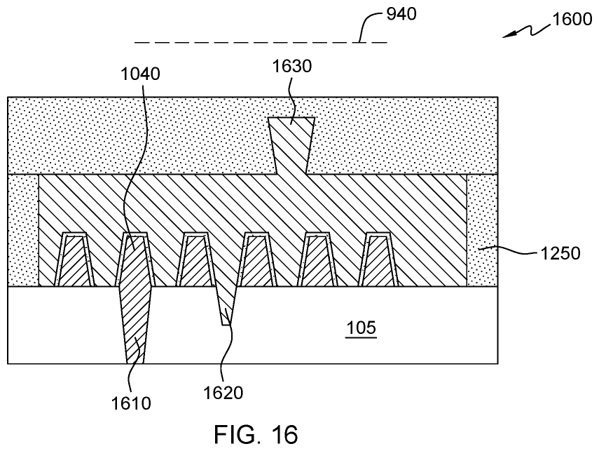

In some embodiments, one or more vias may additionally be formed on top of or below respective metal lines of the first or second sets of metal lines. For example, and as depicted by the cross-sectional view of semiconductor structure 1600 of FIG. 16 taken along corresponding line 940 of FIG. 9, the via 1610 is formed within the substrate 105, and below the metal line 1040 of the first set of metal lines. Similarly, the via 1620 is formed within substrate 105, and below the metal line 1250 of the second set of metal lines. As further depicted by FIG. 16, the via 1630 is formed within an insulating layer, and on top of the metal line 1250 of the second set of metal lines. The vias 1610, 1620, 1630 may be formed using one or more conventional semiconductor manufacturing processes (e.g., a damascene process or a subtractive etch process) for forming a via below or on top of a metal line as known by one of ordinary skill in the art, and as such, a more detailed description of such processes is not presented herein.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

In the preceding, reference is made to embodiments presented in this disclosure. However, the scope of the present disclosure is not limited to specific described embodiments. Instead, any combination of the features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the aspects, features, embodiments and advantages discussed herein are merely illustrative and are not considered elements or limitations of the appended claims except where explicitly recited in a claim(s). Likewise, reference to “the invention” shall not be construed as a generalization of any inventive subject matter disclosed herein and shall not be considered to be an element or limitation of the appended claims except where explicitly recited in a claim(s).

While the foregoing is directed to embodiments of the present invention, other and further embodiments of the invention may be devised without departing from the basic scope thereof, and the scope thereof is determined by the claims that follow.

What is claimed is:

1. A semiconductor interconnect structure, comprising:
a first set of metal lines running along a first orientation; and
a second set of metal lines having an insulating liner and running along a second orientation, wherein the second set of metal lines are embedded within the first set of metal lines at respective cross points between the first and second sets of metal lines, such that the second set of metal lines are located in a same metal level as the first set of metal lines.

2. The semiconductor interconnect structure of claim 1, wherein the first orientation is orthogonal to the second orientation.

3. The semiconductor interconnect structure of claim 1, wherein the first orientation is parallel to the second orientation.

4. The semiconductor interconnect structure of claim 1, wherein:
a top surface of the first set of metal lines is substantially coplanar with a top surface of the second set of metal lines; and
a bottom surface of the first set of metal lines is located below a bottom surface of the second set of metal lines.

5. The semiconductor interconnect structure of claim 1, wherein the insulating liner isolates the second set of metal lines from the first set of metal lines at the respective cross points between the first and second set of metal lines.

6. The semiconductor interconnect structure of claim 1, wherein a first pitch between respective metal lines in the first set of metal lines is greater than a second pitch between respective metal lines in the second set of metal lines.

7. The semiconductor interconnect structure of claim 1, wherein a first pitch between respective metal lines in the first set of metal lines is less than or equal to a second pitch between respective metal lines in the second set of metal lines.

8. A semiconductor interconnect structure, comprising:
a first set of metal lines having an insulating liner and running along a first orientation; and
a second set of metal lines running along a second orientation, wherein the first set of metal lines are encapsulated by the second set of metal lines at respective cross points between the first and second sets of metal lines, such that the first set of metal lines are located in a same metal level as the second set of metal lines.

9. The semiconductor interconnect structure of claim 8, wherein the first orientation is orthogonal to the second orientation.

10. The semiconductor interconnect structure of claim 8, wherein the first orientation is parallel to the second orientation.

11. The semiconductor interconnect structure of claim 8, wherein:
a bottom surface of the first set of metal lines is substantially coplanar with a bottom surface of the second set of metal lines; and
a top surface of the first set of metal lines is located below a top surface of the second set of metal lines.

12. The semiconductor interconnect structure of claim 8, wherein the insulating liner isolates the first set of metal lines from the second set of metal lines at the respective cross points between the first and second set of metal lines.

13. The semiconductor interconnect structure of claim 8, wherein a first pitch between respective metal lines in the first set of metal lines is less than a second pitch between respective metal lines in the second set of metal lines.

14. The semiconductor interconnect structure of claim 8, wherein a first pitch between respective metal lines in the first set of metal lines is greater than or equal to a second pitch between respective metal lines in the second set of metal lines.

15. A method of forming a semiconductor interconnect structure, comprising:
forming a first set of metal lines running along a first orientation; and
forming a second set of metal lines running along a second orientation, such that the second set of metal lines intersect the first set of metal lines at respective cross points between the first and second set of metal lines, and the second set of metal lines are located in a same metal level as the first set of metal lines.

16. The method of claim 15, wherein forming the first set of metal lines running along the first orientation includes:
depositing a first insulating material onto a substrate to form an insulating layer;
etching the insulating layer to form a first set of line openings within the insulating layer;
depositing a metal liner material to form a metal liner within the first set of line openings; and
depositing a first conductive metal material on top of the metal liner to fill the first set of line openings.

17. The method of claim 16, wherein forming the first second set of metal lines running along the second orientation includes:
etching the first conductive metal material of the first set of lines to form a second set of line openings within the first set of metal lines;
conformally depositing a second insulating material to form an insulating liner within the second set of line openings; and
depositing a second conductive metal material on top of the insulating liner to fill the second set of line openings.

18. The method of claim 15, wherein the first orientation that the first set of metal lines run along is orthogonal to the second orientation that the second set of metal lines run along.

19. The method of claim 15, wherein forming the first set of metal lines running along the first orientation includes:
depositing a first conductive metal material onto a substrate; and
patterning, using subtractive etching, the first conductive metal material to form the first set of metal lines.

20. The method of claim 19, wherein forming the second set of metal lines running along the second orientation includes:
conformally depositing a first insulating material onto the first set of metal lines to form an insulating liner;
depositing a second conductive metal material onto the insulating liner; and
etching the second conductive metal material to form the second set of metal lines.
